(19) United States
(12) Patent Application Publication
(10) Pub. No.: US 2026/0086546 A1
(43) Pub. Date: Mar. 26, 2026

(54) ABNORMALITY MANAGEMENT METHOD, MANAGEMENT DEVICE, AND STORAGE MEDIUM

(71) Applicant: Tokyo Electron Limited, Minato-ku, Tokyo (JP)

(72) Inventor: Shuji IWANAGA, Koshi City, Kumamoto (JP)

(21) Appl. No.: 19/109,289

(22) PCT Filed: Aug. 24, 2023
(86) PCT No.: PCT/JP2023/030597

§ 371 Date: Mar. 6, 2025

(30) Foreign Application Priority Data
Sep. 7, 2022 (JP) 2022-142056
Jul. 5, 2023 (JP) 2023-110683

(51) Int. Cl. G05B 23/02

(52) U.S. Cl. CPC G05B 23/0221

(57) ABSTRACT

An abnormality management method used in a substrate transfer device includes: an acquisition operation of acquiring target data, which is transition data of an abnormality scale calculated based on a feature amount relating to a transfer operation of the substrate transfer device; a specification operation of comparing the target data acquired in the acquisition operation with plural pieces of reference data and specifying at least one piece of the reference data similar to the target data among the plural pieces of reference data based on a comparison result; an estimation operation of estimating an abnormality occurrence prediction time in the substrate transfer device from which the target data has been acquired, based on an abnormality occurrence time in the at least one piece of reference data specified in the specification operation; and an output operation of outputting information which indicates the abnormality occurrence prediction time estimated in the estimation operation.

### TECHNICAL FIELD

The present disclosure relates to an abnormality management method, a management apparatus, and a storage medium.

### BACKGROUND

Patent Document 1 discloses a monitoring method of a transfer unit which transfers an object to be transferred. Specifically, Patent Document 1 discloses calculating a health level of the transfer unit for an object to be monitored based on a relationship model obtained by machine learning and status values of multiple types obtained with respect to the transfer unit for the object to be monitored. Patent Document 1 also discloses outputting information about a status of the transfer unit for the object to be monitored according to the calculated health level.

### PRIOR ART DOCUMENT

### Patent Document

Patent Document 1: Japanese Laid-Open Patent Publication No. 2020-086694

### SUMMARY

The present disclosure provides an abnormality management method and a management apparatus which are capable of predicting occurrence of abnormality relating to a substrate transfer device with high accuracy, and a storage medium.

According to one aspect of the present disclosure, an abnormality management method used in a substrate transfer device configured to transfer a substrate includes: an acquisition operation of acquiring target data, which is transition data of an abnormality scale calculated based on a feature amount relating to a transfer operation of the substrate transfer device; a specification operation of comparing the target data acquired in the acquisition operation with a plurality of pieces of reference data, which is pre-stored transition data acquired in a previous operation and determined to be abnormal, and specifying at least one piece of the reference data similar to the target data among the plurality of pieces of reference data based on a result of the comparison; an estimation operation of estimating an abnormality occurrence prediction time in the substrate transfer device from which the target data has been acquired, based on an abnormality occurrence time in the at least one piece of reference data specified in the specification operation; and an output operation of outputting information which indicates the abnormality occurrence prediction time estimated in the estimation operation.

According to the present disclosure, it is possible to predict occurrence of abnormality relating to a substrate transfer device with high accuracy.

### BRIEF DESCRIPTION OF DRAWINGS

FIG. 1 is a perspective view illustrating a substrate processing system.

FIG. 2 is a cross-sectional view taken along line II-II in FIG. 1.

FIG. 3 is a cross-sectional view taken along line III-III in FIG. 2.

FIG. 4 is a diagram for explaining a configuration of a transfer arm.

FIG. 5 is a longitudinal cross-sectional side view schematically illustrating a coating unit.

FIGS. 6A and 6B are diagrams for explaining delivery of a wafer from a transfer arm to a spin chuck.

FIG. 7 is a schematic diagram illustrating a functional configuration of a controller.

FIG. 8 is a diagram illustrating an example of a user-visible image.

FIG. 9 is a diagram illustrating another example of the user-visible image.

FIG. 10 is a schematic diagram illustrating a hardware configuration of the controller.

FIG. 11 is a flowchart illustrating a procedure of an abnormality management method.

FIG. 12 is a diagram for explaining comparison of movement trajectories and setting a threshold of an abnormality scale.

FIGS. 13A and 13B are diagrams for explaining an exponential degradation model.

FIGS. 14A and 14B are diagrams for explaining effects of theta and beta in the exponential degradation model.

FIGS. 15A and 15B are diagrams for explaining an estimation of a remaining useful life.

FIGS. 16A to 16C are diagrams for explaining an estimation result of the remaining useful life when an initial value of a parameter is close to an optimal value.

FIGS. 17A to 17C are diagrams for explaining the estimation result of the remaining useful life when the initial value of the parameter deviates from the optimal value.

FIG. 18 is a flowchart illustrating a procedure of an abnormality management method according to a modification example.

### DETAILED DESCRIPTION

Hereinafter, embodiments of the present disclosure will be described in detail with reference to the accompanying drawings. In describing the embodiments, the same elements or elements having the same function will be denoted by the same reference numerals, and redundant description thereof will be omitted.

### Configuration of Substrate Processing System

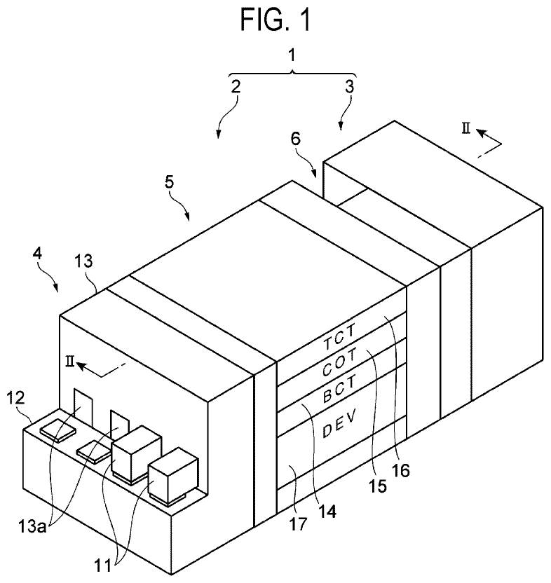

As illustrated in FIG. 1, a substrate processing system 1 includes a coating/developing apparatus 2 and an exposure apparatus 3. The exposure apparatus 3 performs an exposure process on a resist film. Specifically, the exposure apparatus 3 irradiates an exposure target portion of the resist film (photosensitive coating film) with energy rays by a method such as immersion exposure. An example of the energy rays may include an ArF excimer laser, a KrF excimer laser, g-rays, i-rays, or extreme ultraviolet (EUV).

The coating/developing apparatus 2 is a substrate processing apparatus which performs a process of forming a resist film on a surface of a wafer (substrate) W before an exposure process by the exposure apparatus 3, and performs a developing process on the resist film after the exposure process. In the present embodiment, the coating/developing apparatus 2 functions as a management apparatus for a substrate transfer device (described in detail later) which transfers the wafer W. In the present embodiment, the coating/developing apparatus 2 is described as the management apparatus for the substrate transfer device, but an external server of the substrate processing system 1 may function as the management apparatus. In the present embodiment, the wafer W has a disc shape. A wafer in which a part of a circle is cut out or a wafer having a shape such as a polygonal shape other than a circle may be used as the wafer W. The wafer W may be, for example, a semiconductor substrate, a glass substrate, a mask substrate, a flat panel display (FPD) substrate, or other various substrates.

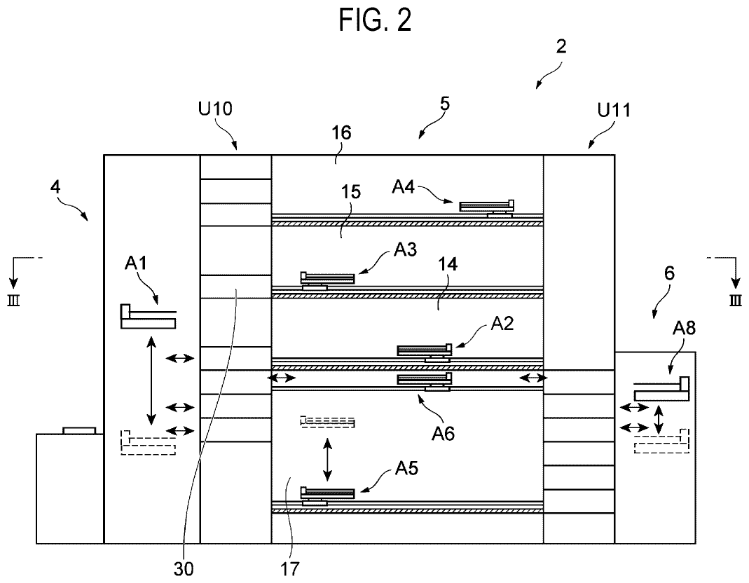

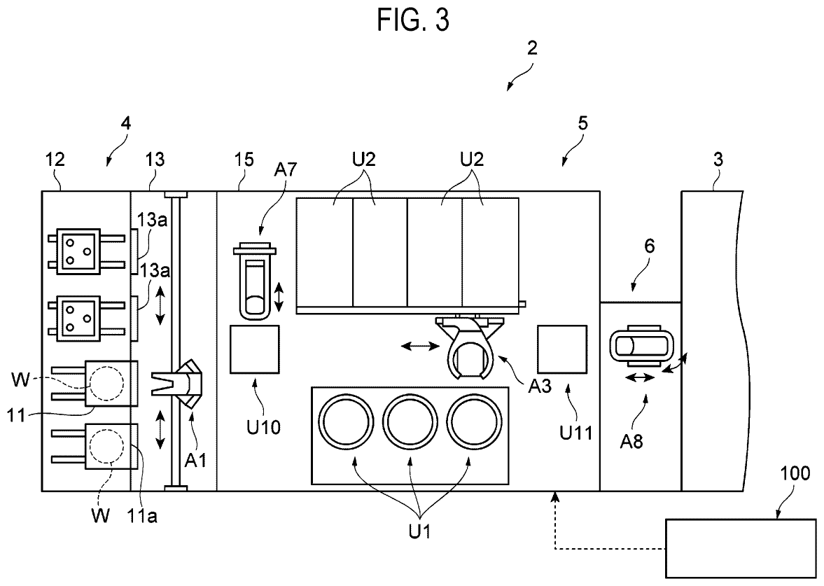

As illustrated in FIGS. 1 to 3, the coating/developing apparatus 2 includes a carrier block 4, a processing block 5, an interface block 6, and a controller (control part) 100 (see FIG. 3). The carrier block 4, the processing block 5, and the interface block 6 are aligned in a horizontal direction.

The carrier block 4 includes a carrier station 12 and a loading/unloading section 13. The loading/unloading section 13 is interposed between the carrier station 12 and the processing block 5. The carrier station 12 supports a plurality of carriers 11. The carrier 11 accommodates, for example, a plurality of circular wafers W in a sealed state and includes an opening/closing door (not illustrated) for loading and unloading the wafers W therethrough on a side surface 11a. The carrier 11 is detachably installed on the carrier station 12 so that the side surface 11a faces the loading/unloading section 13. The loading/unloading section 13 includes a plurality of opening/closing doors 13a corresponding respectively to the plurality of carriers 11 on the carrier station 12. By simultaneously opening the opening/closing door on the side surface 11a and the opening/closing doors 13a, an interior of each of the carriers 11 communicates with an interior of the loading/unloading section 13. The loading/unloading section 13 incorporates a delivery arm A1. The delivery arm Al takes the wafer W out of the carrier 11 and delivers the same to the processing block 5. The delivery arm Al receives the wafer W from the processing block 5 and returns the same back to the carrier 11.

The processing block 5 includes a BCT module (lower layer film formation module) 14, a COT module (resist film formation module) 15, a TCT module (upper layer film formation module) 16, and a DEV module (developing processing module) 17. These modules are arranged in order of the DEV module 17, the BCT module 14, the COT module 15, and the TCT module 16 from a floor surface side.

The BCT module 14 is configured to form a lower layer film on the surface of the wafer W. The BCT module 14 incorporates a plurality of coating units (not illustrated), a plurality of heating units (not illustrated), and a transfer arm A2 for transferring the wafer W to these units. Each coating unit is configured to coat the surface of the wafer W with a coating liquid for forming the lower layer film. Each heating unit is configured to perform heating process on the wafer W by heating the wafer W using, for example, a hot plate, and cooling the heated wafer W using, for example, a cooling plate. A specific example of the heating process performed in the BCT module 14 is a heating process for hardening the coating liquid.

The COT module 15 is configured to form a photosensitive thermosetting resist film on the lower layer film. The COT module 15 incorporates a plurality of coating units U1, a plurality of heating units U2, and a transfer arm A3 (substrate transfer device) for transferring the wafer W to these units. In this embodiment, the transfer arm A3 is described as an example of the “substrate transfer device,” but other transfer arms or delivery arms may be examples of the “substrate transfer device.” The coating unit U1 is configured to coat the lower layer film with a coating liquid (resist agent) for forming the resist film. The heating unit U2 is configured to perform a heating process by heating the wafer W using, for example, a hot plate and cooling the heated wafer W using, for example, a cooling plate. A specific example of the heating process performed in the COT module 15 is a heating process (pre-applied bake (PAB)) for hardening the coating liquid.

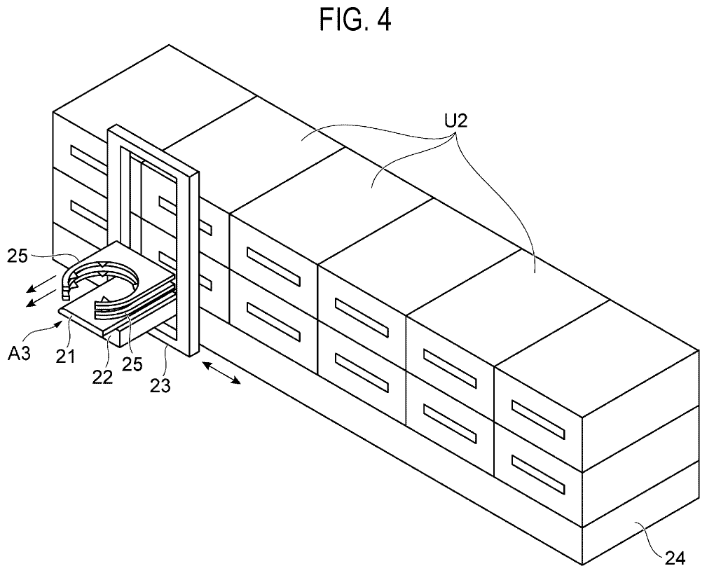

FIG. 4 is a diagram for explaining a configuration of the transfer arm A3 described above. As illustrated in FIG. 4, the transfer arm A3 includes a plurality of holders 25 for holding the wafer W, a base 21, a lifting platform 22, and a frame 23. The holders 25 are provided on the base 21 so as to vertically overlap each other, and move horizontally forward and backward on the base 21 independently of each other. The holders 25 hold the wafer W by surrounding a lateral periphery of the wafer W and supporting a rear surface of the wafer W. The base 21 is provided on the lifting platform 22 and rotates about a vertical axis. The lifting platform 22 is provided so as to be surrounded by the frame 23 extending in a vertical direction. The frame 23 is connected to a housing 24 and configured to be movable along the housing 24.

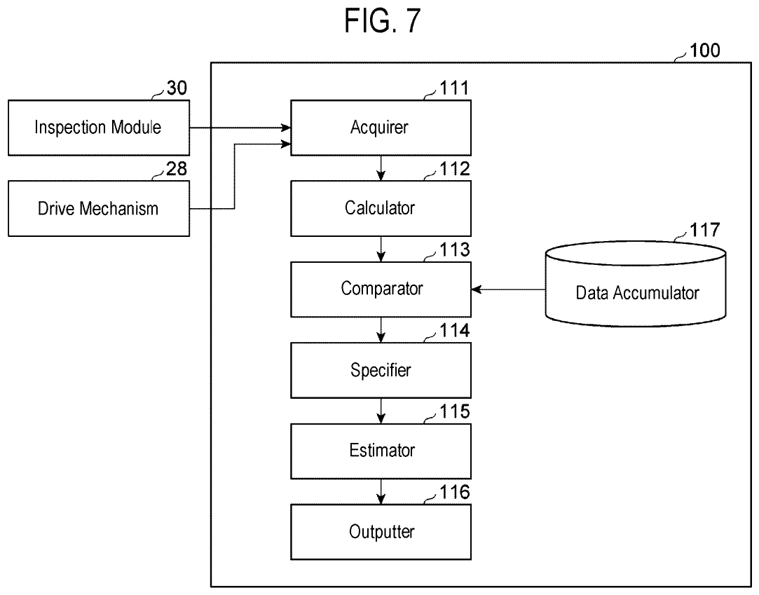

The base 21 is provided with a drive mechanism for moving the holders 25 forward and backward. The lifting platform 22 is provided with a drive mechanism for rotating the base 21. The frame 23 is provided with a drive mechanism for raising and lowering the lifting platform 22. The housing 24 is provided with a drive mechanism for moving the frame 23. Each drive mechanism includes a motor, a pulley, and a belt wound around the motor and the pulley. A rotational motion of each motor is converted into a linear motion by each belt, so that the frame 23, the lifting platform 22, and the holder 25 move. The base 21 rotates with the rotation of the pulley. Hereinafter, in some cases, the above-mentioned drive mechanisms are collectively referred to as a “drive mechanism 28” (see FIG. 7). For example, the drive mechanism 28 transmits torque data relating to driving the transfer arm A3 to the controller 100.

Returning back to FIGS. 1 to 3, the TCT module 16 is configured to form an upper layer film on the resist film. The TCT module 16 incorporates a plurality of coating units (not illustrated), a plurality of heating units (not illustrated), and a transfer arm A4 which transfers the wafer W to these units. The coating unit is configured to coat the surface of the wafer W with a coating liquid for forming the upper layer film. The heating unit is configured to perform a heating process by heating the wafer W using, for example, a hot plate and cooling the heated wafer W using, for example, a cooling plate. A specific example of the heating process performed in the TCT module 16 is a heating process for hardening the coating liquid.

The DEV module 17 is configured to perform a developing process on an exposed resist film. The DEV module 17 incorporates a plurality of developing units (not illustrated), a plurality of heating units (not illustrated), a transfer arm A5 for transferring the wafer W to these units, and a direct transfer arm A6 for transferring the wafer W without passing through these units. The developing unit is configured to partially remove the resist film to form a resist pattern. The heating unit performs the heating process on the wafer W by heating the wafer W using, for example, a hot plate, and cooling the heated wafer W using, for example, a cooling plate. Specific examples of the heating process performed in the DEV module 17 include a heating process before the developing process (post exposure bake (PEB)) and heating process after the developing process (post-bake (PB)).

A shelf unit U10 is provided on a side of the carrier block 4 in the processing block 5. The shelf unit U10 is provided so as to extend from a bottom surface to the TCT module 16 and is partitioned into a plurality of cells arranged in a vertical direction. A lifting arm A7 is provided near the shelf unit U10. The lifting arm A7 raises and lowers the wafer W between the cells of the shelf unit U10.

Further, the shelf unit U10 is provided with an inspection module 30. The inspection module 30 is an image acquisition module. The inspection module 30 includes a stage on which the wafer W is placed, and a camera for capturing an image of a surface of the wafer W placed on the stage. The inspection module 30 captures the image of the surface of the wafer W by the camera after the coating process by the coating unit Ul and transmits image data thus obtained to the controller 100. The controller 100 may detect a cut width of the resist film based on the image data, as described below.

A shelf unit U11 is provided on a side of the interface block 6 in the processing block 5. The shelf unit U11 is provided so as to extend from the bottom surface to an upper portion of the DEV module 17, and is partitioned into a plurality of cells arranged in a vertical direction.

The interface block 6 incorporates a delivery arm A8 and is connected to the exposure apparatus 3. The delivery arm A8 is configured to take the wafer W out of the shelf unit U11 and deliver the same to the exposure apparatus 3. Further, the delivery arm A8 is configured to receive the wafer W from the exposure apparatus 3 and return the same back to the shelf unit U11.

The controller 100 is configured with one or more control computers and performs control in the coating/developing apparatus 2. The controller 100 includes a display (not illustrated) that displays a setting screen for control conditions, an input part (not illustrated) that inputs the control conditions, and a reading part (not illustrated) that reads a program from a computer-readable recording medium. The recording medium records a program for causing the coating/developing apparatus 2 to execute processing. The program is read by the reading part of the controller 100. Examples of the recording medium may include a semiconductor memory, an optical recording disc, a magnetic recording disk, and a magneto-optical recording disc. The controller 100 controls the coating/developing apparatus 2 based on the control conditions input to the input part and the program read by the reading part.

### Configuration of Coating Unit

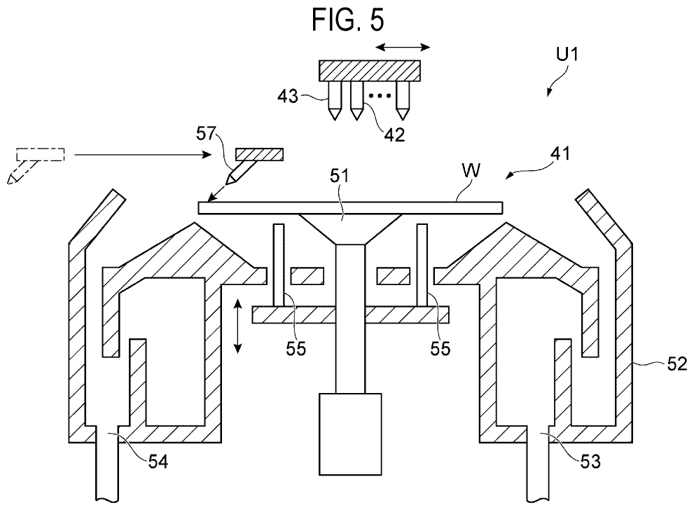

Next, the coating unit U1 will be described with reference to FIG. 5. The coating unit Ul includes, for example, two processors 41, a plurality of resist supply nozzles 42, a solvent supply nozzle 43, and a peripheral-portion solvent supply nozzle 57. The resist supply nozzles 42 and the solvent supply nozzle 43 are shared by the two processors 41 and may be positioned above the wafer W of the two processors 41. Only one processor 41 is illustrated in FIG. 5. Hereinafter, for the sake of simplification in description, only the configuration relating to one processor 41 will be described.

The processor 41 includes a spin chuck 51 which attracts and holds a back surface of the wafer W, a cup 52 which surrounds the periphery of the spin chuck 51 and has an open upper portion, an exhaust port 53 which exhausts an interior of the cup 52, and a drain port 54. The processor 41 further includes lifting pins 55 which deliver the wafer W between the spin chuck 51 and the transfer arm A3.

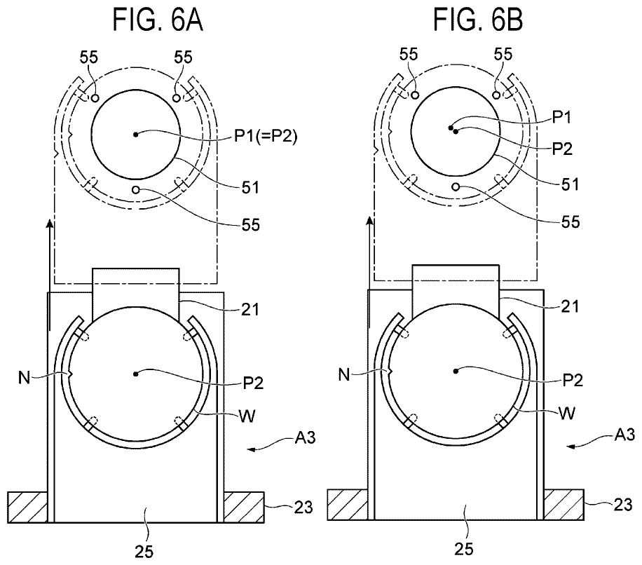

A processing flow of the wafer W in the coating unit U1 will now be described. First, the holder 25 of the transfer arm A3 receives the wafer W. The transfer arm A3 transfers the wafer W toward the spin chuck 51. When the holder 25 moves close to the spin chuck 51, the base 21 rotates, and the holder 25 is arranged so as to face the front of the spin chuck 51, as illustrated by a solid line in FIG. 6A. Thereafter, the holder 25 advances above the base 21 and transfers the wafer W to a delivery position of the spin chuck 51, as illustrated by a dashed line in FIG. 6A. Subsequently, the wafer W is supported by three raised lifting pins 55 and is delivered to the spin chuck 51 by moving the holder 25 backward and lowering the lifting pins 55.

Then, the wafer W is rotated by the spin chuck 51, and thinner is discharged from the solvent supply nozzle 43 toward the center of the wafer W. The thinner is spread to a peripheral portion of the wafer W by virtue of a centrifugal force. Further, resist is supplied to the center of the wafer W from the resist supply nozzle 42 so that a resist film is formed on the entirety of the wafer W by spin coating. Thereafter, the peripheral-portion solvent supply nozzle 57 moves from a standby position outside the cup 52 to a solvent processing position inside the cup 52, and discharges a solvent to the peripheral portion of the wafer W under rotation. The solvent spreads from a solvent discharge position to the peripheral portion of the wafer W by the centrifugal force of the wafer W so that an unnecessary portion of the peripheral portion of the wafer W is removed in a ring shape. Then, the supply of the solvent and the rotation of the wafer W are stopped and the processing ends. The wafer W is unloaded from the coating unit U1 by the transfer arm A3.

Here, as illustrated in FIG. 6A, the delivery position of the wafer W with respect to the spin chuck 51 may be a position at which a rotational center P1 of the spin chuck 51 and a center P2 of the wafer W coincide with each other. When the rotational center P1 and the center P2 of the wafer W coincide with each other in this way, the center of the resist film from which the unnecessary portion has been removed coincides with the center P2 of the wafer W. However, there may be cases in which a belt of each drive mechanism loosens or teeth of the belt fall out due to a time-dependent deterioration of the transfer arm A3. In this case, for example, as illustrated in FIG. 6B, the rotational center P1 and the center P2 of the wafer W may not coincide with each other so that the delivery position of the wafer W with respect to the spin chuck 51 deviates. As a result, the center of the resist film is decentered with respect to the center P2 of the wafer W. In this embodiment, the controller 100 estimates a decentering amount from a cut width of the resist film on the wafer W (a removed width of the resist film) based on the image data obtained from the inspection module 30 (details thereof will be described later). Subsequently, the controller 100 calculates a health level (a degree of the time-dependent deterioration) of the transfer arm A3 in consideration of a feature amount in addition to the decentering amount, and estimates an abnormality occurrence prediction time of the transfer arm A3 (details thereof will be described later).

### Function of Controller

Next, a function of the controller 100 in relation to an abnormality management method of managing an abnormality of the transfer arm A3 will be described with reference to FIG. 7. As illustrated in FIG. 7, the controller 100 includes an acquirer 111, a calculator 112, a comparator 113, a specifier 114, an estimator 115, and an outputter 116.

The acquirer 111 acquires a feature amount relating to a transfer operation of the transfer arm A3. The acquirer 111 continues to acquire the feature amount at predetermined time intervals, for example, after the transfer arm A3 starts to operate. The acquirer 111 acquires, for example, from the inspection module 30, image data obtained by capturing an image of the surface of the wafer W by the camera after the coating process by the coating unit U1. The image data is data capable of specifying the cut width of the resist film (the removal width of the resist film) on the wafer W. The acquirer 111 estimates the decentering amount of the resist film on the wafer W (information about an amount of deviation from a target transfer position of the wafer W transferred by the transfer arm A3), for example, from the cut width of the resist film indicated in the image data. Then, the acquirer 111 acquires the decentering amount as the feature amount relating to the transfer operation of the transfer arm A3. Further, the acquirer 111 may acquire, from the drive mechanism 28, torque data relating to the driving of the transfer arm A3 as the feature amount relating to the transfer operation of the transfer arm A3. Hereinafter, both the decentering amount and the torque data will be described as the feature amount. However, only one of the decentering amount and the torque data may be regarded as the feature amount, and other information relating to the transfer operation of the transfer arm A3 may be regarded as the feature amount. Further, the acquirer 111 acquires information including at least one of a type of the transfer arm A3, a type of the substrate processing apparatus in which the transfer arm A3 is included, or a usage status of the transfer arm A3, as supplementary information associated with target data (to be described later). Examples of the usage status of the transfer arm A3 may include an average number of operations of the transfer arm A3 (10,000 times/day, or the like) and an average transfer speed.

The calculator 112 calculates (acquires) the target data, which is transition data of an abnormality scale, based on the feature amount acquired by the acquirer 111. The abnormality scale used herein is an indicator of a health level in consideration of the time-dependent deterioration of the transfer arm A3. For example, the abnormality scale may be set to a lower value as the health level decreases (as the time-dependent deterioration progresses) to approach an abnormality occurrence time. For example, the calculator 112 may calculate the abnormality scale by inputting the feature amount to a degradation model that has been constructed in advance. In this case, the degradation model may be a model constructed by training, for example, a plurality of pieces of learning data. The calculator 112 calculates the target data, which is the transition data of the abnormality scale, by calculating the abnormality scale for each of feature amounts acquired at predetermined time intervals. In other words, the target data is data in which the abnormality scale at each time from the start of the transfer operation of the transfer arm A3 to the current time is specified for the transfer arm A3. A method of calculating the abnormality scale from the feature amount is not limited to the above example.

The comparator 113 compares the acquired target data with a plurality of pieces of reference data, which is pre-stored transition data acquired in a previous operation and defined as an abnormality occurrence. The comparator 113 acquires the plurality of pieces of reference data accumulated in a data accumulator 117. The reference data is data in which an abnormality scale is specified at each time from the start of a transfer operation of another transfer arm to the occurrence of abnormality (until the transfer arm become inoperable). Further, the comparator 113 acquires supplementary information associated with the reference data from the data accumulator 117. The supplementary information is information including at least one of a type of the transfer arm (the substrate transfer device), a type of the substrate processing apparatus in which the transfer arm is included, or a usage status of the transfer arm. Examples of the usage status of the transfer arm may include an average number of operations of the transfer arm (10,000 times/day, or the like), an average transfer speed, and the number of days until the abnormality occurs.

The comparator 113 compares an abnormality scale in a first duration from a starting point (a time when the transfer operation starts) in the target data to a predetermined time (for example, a current time) with an abnormality scale in a comparison target duration from a starting point in the plurality of pieces of reference data to a time when a length equivalent to the first duration has elapsed. In addition, the comparator 113 further compares the supplementary information associated with the target data with the supplementary information associated with each of the plurality of pieces of reference data.

The specifier 114 specifies at least one piece of the reference data similar to the target data, based on comparison results relating to the abnormality scales obtained by the comparator 113. The specifier 114 may specify the reference data in consideration of comparison results relating to the supplementary information (in further consideration of similarity of the supplementary information). That is, the specifier 114 may specify pieces of reference data in which the transitions of the abnormality scale is similar to each other, and the type of the transfer arm, the type of the substrate processing apparatus, the usage status of the transfer arm, or the like are similar to each other.

The estimator 115 estimates the abnormality occurrence prediction time relating to the transfer arm A3 from which the target data has been acquired, based on an abnormality occurrence time in at least one piece of reference data specified by the specifier 114. The estimator 115 may estimate the abnormality occurrence time of the reference data as the abnormality occurrence prediction time in the target data. In addition, the estimator 115 may estimate the abnormality occurrence prediction time in the reference data from the abnormality occurrence time in the reference data in consideration of a difference in transition of the abnormality scales between the reference data and the target data.

The outputter 116 outputs information indicating the abnormality occurrence prediction time thus estimated. The outputter 116 outputs (displays) a user-visible image. Specifically, the outputter 116 outputs the user-visible image in which a trajectory of the target data corresponds to the abnormality occurrence prediction time on a graph. Further, the outputter 116 may output the user-visible image including a prediction trajectory that connects an end point of the trajectory of the target data and the abnormality occurrence prediction time on the graph.

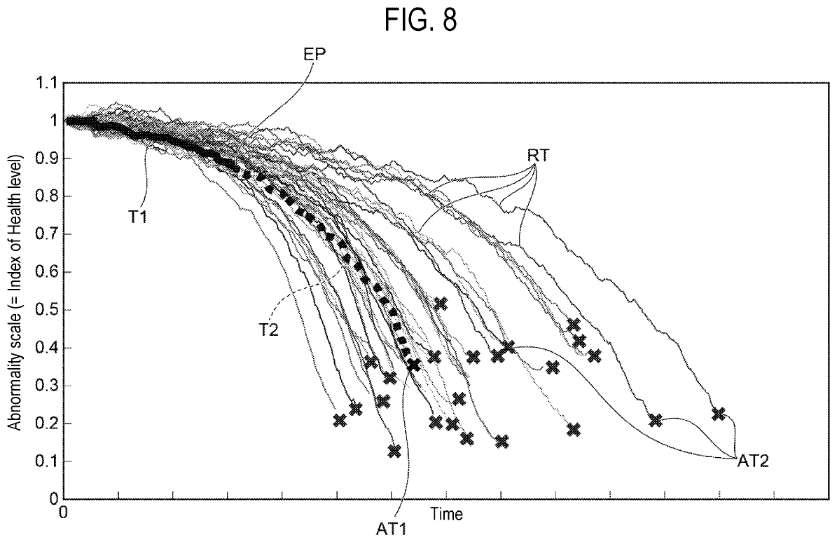

FIG. 8 is a diagram illustrating an example of the user-visible image. In FIG. 8, the horizontal axis represents the time, and the vertical axis represents the abnormality scale. The abnormality scale is set to “1” at the start of the transfer operation. As the health level decreases (as the time-dependent deterioration progresses), the abnormality scale is set to a lower value to approach the abnormality occurrence time. In the user-visible image illustrated in FIG. 8, a plurality of trajectories RT of the reference data is illustrated. In each trajectory RT of the reference data, an abnormality occurrence time AT2 is denoted by a symbol “x.” In the user-visible image illustrated in FIG. 8, a trajectory T1 of the target data is denoted by a thick solid line so as to be aligned with each trajectory RT of the reference data. In addition, an abnormality occurrence prediction time AT1 estimated for the target data is denoted by the symbol “x.” Further, a prediction trajectory T2 connecting an end point EP of the trajectory T1 of the target data and the abnormality occurrence prediction time AT1 is denoted by a thick dotted line.

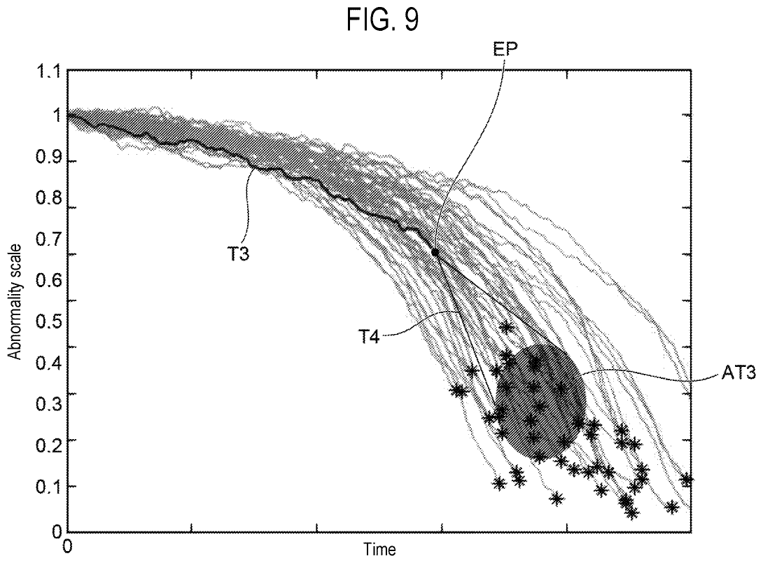

FIG. 9 is a diagram illustrating another example of the user-visible image. In FIG. 9, the horizontal axis indicates the time, and the vertical axis indicates the abnormality scale. In the user visual image illustrated in FIG. 9, a trajectory T3 of the target data is represented by a thick solid line. Here, in the example illustrated in FIG. 9, for example, due to circumstances such as the existence of a plurality of pieces of specified reference data, an abnormality occurrence prediction time AT3 is illustrated by an area rather than a single point. In addition, a prediction trajectory T4 connecting an end point EP of the trajectory T3 of the target data and the area of the abnormality occurrence prediction time AT3 is represented by a thin solid line. In this way, by displaying the abnormality occurrence prediction time AT3 as an area having a certain size rather than as a pinpoint like, for example, a predicted path of a typhoon, it is possible for a user to more easily predict the occurrence of abnormality.

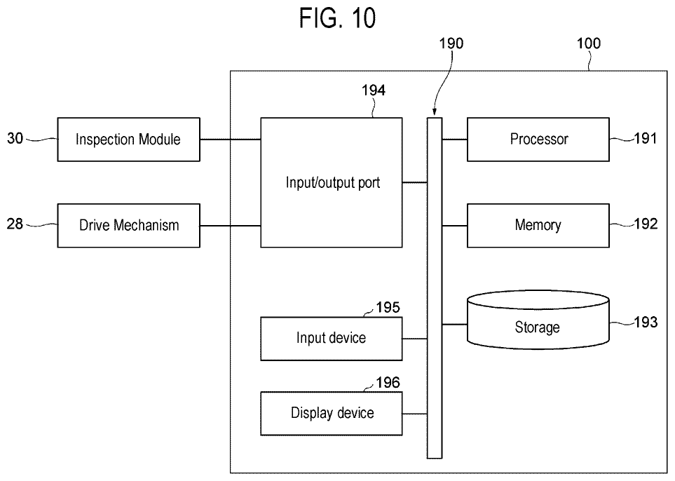

FIG. 10 is a schematic diagram illustrating a hardware configuration of the controller 100. The controller 100 is constituted with one or more control computers. As illustrated in FIG. 10, the controller 100 includes a circuit 190. The circuit 190 includes at least one processor 191, a memory 192, a storage 193, an input/output port 194, an input device 195, and a display device 196.

The storage 193 includes a computer-readable storage medium such as a hard disk. The storage 193 stores a program for causing the controller 100 to execute an abnormality management method for the transfer arm A3 by the coating/developing apparatus 2. For example, the storage 193 stores a program for causing the controller 100 to execute each of the above-described functional blocks.

The memory 192 temporarily stores the program loaded from the storage medium of the storage 193 and results calculated by the processor 191. The processor 191 configures each of the above-described functional modules by executing the program in cooperation with the memory 192. The input/output port 194 inputs and outputs electric signals to and from the inspection module 30 and the drive mechanism 28 according to commands provided from the processor 191.

The input device 195 and the display device 196 function as user interfaces of the controller 100. The input device 195 is, for example, a keyboard, and acquires information input by the user. The display device 196 includes, for example, a liquid crystal monitor, and is used to display information about the user (display, for example, the above-described user-visible image). As an example, the display device 196 is used to display the above-described factor information. The input device 195 and the display device 196 may be integrated together as a so-called touch panel.

### Abnormality Management Method for Transfer Arm

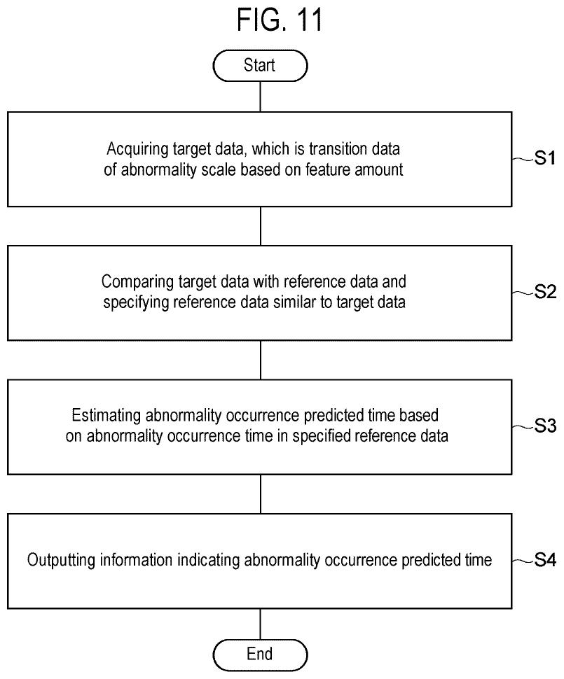

Next, a procedure of the abnormality management method for the transfer arm A3 executed by the controller 100 will be described with reference to FIG. 11. FIG. 11 is a flowchart illustrating the procedure of the abnormality management method.

As illustrated in FIG. 11, first, the target data, which is the transition data of the abnormality scale calculated based on the feature amount relating to the transfer operation of the transfer arm A3, is acquired (Step S1, an acquisition operation).

Subsequently, the target data acquired in Step S1 is compared with the reference data acquired in a previous operation and stored in advance, and one or more pieces of the reference data similar to the target data are specified based on results of the comparison (Step S2, a specification operation). In the specification operation, the abnormality scale in a first duration from a starting point to an end point in the target data may be compared with the abnormality scale in a comparison target duration from a starting point in the plurality of pieces of reference data to a time when a length equivalent to the first duration has elapsed. Then, at least one piece of the reference data similar to the target data may be specified. In addition, in the specification operation, supplementary information associated with the target data may be further compared with supplementary information associated with each of the plurality of pieces of reference data, and the reference data may be specified in consideration of similarity of the supplementary information.

Subsequently, based on an abnormality occurrence time in the at least one piece of reference data specified in Step S2, an abnormality occurrence prediction time relating to the transfer arm A3 from which the target data has been acquired is estimated (Step S3, an estimation operation).

Subsequently, information indicating the abnormality occurrence prediction time estimated in Step S3 is output (Step S4, an output operation). In the output operation, a user-visible image in which a trajectory of the target data and the abnormality occurrence prediction time are associated with each other on a graph may be output. Further, in the output operation, the user-visible image including a prediction trajectory which connects an end point of the trajectory of the target data and the abnormality occurrence prediction time on the graph may be output.

### Operation Effects

Next, operation effects of the abnormality management method for the transfer arm A3 according to the present embodiment will be described.

The abnormality management method for the transfer arm A3 according to the present embodiment is an abnormality management method used in the transfer arm A3 configured to transfer the wafer W. The abnormality management method includes the acquisition operation of acquiring the target data, which is the transition data of the abnormality scale calculated based on the feature amount relating to the transfer operation of the transfer arm A3. In the abnormality management method, the target data acquired in the acquisition operation is compared with the plurality of pieces of reference data, which is pre-stored transition data acquired in a previous operation and defined as the occurrence of abnormality. The abnormality management method includes the specification operation of specifying at least one piece of the reference data similar to the target data based on results of the comparison. The abnormality management method includes the estimation operation of estimating the abnormality occurrence prediction time relating to the transfer arm A3 from which the target data has been acquired, based on the abnormality occurrence time in the at least one piece of reference data specified in the specification operation. The abnormality management method includes the output operation of outputting the information indicating the abnormality occurrence prediction time estimated in the estimation operation.

In the abnormality management method for the transfer arm A3 according to the embodiment, the target data, which is the transition data of the abnormality scale calculated based on the feature amount relating to the transfer operation, is compared with the plurality of pieces of reference data, which is pre-stored transition data acquired in a previous operation and defined as the occurrence of abnormality. Then, the reference data similar to the target data is specified, the abnormality occurrence prediction time relating to the transfer arm A3 from which the target data has been acquired is estimated based on the abnormality occurrence time in the reference data, and the abnormality occurrence prediction time is output. With this configuration, the abnormality occurrence prediction time of the target data is estimated from the abnormality occurrence time of the reference data having a similar transition of the abnormality scale, which makes it possible to more precisely predict the abnormality occurrence prediction time relating to the transfer arm A3 from which the target data has been acquired. In addition, in the abnormality management method, the transition data of the abnormality scale calculated based on the feature amount relating to the transfer operation is used for the comparison. Therefore, the above-described comparison may be applied to, for example, different substrate transfer devices and different substrate processing apparatuses. This makes it possible to predict and diagnose abnormality with a unified abnormality indicator.

In the specification operation, the abnormality scale in the first duration from the starting point in the target data to the predetermined time is compared with the abnormality scale in the comparison target duration from the starting point in the plurality of pieces of reference data to the time when the length equivalent to the first duration has elapsed. Then, the at least one piece of reference data similar to the target data may be specified. With this configuration, by comparing durations of the same length from the starting point to the predetermined time with each other, it is possible to specify reference data having a relatively high similarity to the target data. As a result, the abnormality occurrence prediction time relating to the transfer arm A3 from which the target data has been acquired may be predicted with high accuracy.

The target data and the plurality of pieces of reference data are associated with the supplementary information including at least one of the type of the substrate transfer device, the type of the substrate processing apparatus equipped with the substrate transfer device, or the usage condition of the substrate transfer device. In the specification operation, the supplementary information associated with the target data may further be compared with the supplementary information associated with each of the plurality of pieces of reference data, and the reference data may be specified in consideration of similarity between the pieces of supplementary information. In this way, by further considering the similarity between the pieces of supplementary information such as the usage condition of the substrate transfer device, it is possible to specify the reference data, a trajectory of which is considered to be more similar up to the occurrence of abnormality. As a result, the abnormality occurrence prediction time in the substrate transfer device from which the target data has been acquired may be predicted with high accuracy.

In the output operation, the user-visible image in which the trajectory of the target data and the abnormality occurrence prediction time are associated with each other on a graph may be output. With this configuration, it is possible to present the abnormality occurrence prediction time together with reasons thereof (the transition of the abnormality scale) to the user. This makes it possible to present the abnormality occurrence prediction time having a relatively high estimation reliability to the user, thereby allowing the user to efficiently perform planned productive maintenance (PM) before the occurrence of abnormality.

In the output operation, the user-visual image including the prediction trajectory which connects the end point of the trajectory of the target data and the abnormality occurrence prediction time on the graph may be output. Thus, the trajectory of the target data and the abnormality occurrence prediction time may be presented to the user as a continuous trajectory, and the abnormality occurrence prediction time having a high estimation reliability may be presented to the user. This makes it possible to present the abnormality occurrence prediction time having a high estimation reliability to the user, thereby allowing the user to efficiently perform the planned PM before the occurrence of abnormality.

The feature amount may include the information about the amount of deviation of the wafer W transferred by the transfer arm A3 from the target transfer position. By using the information about the amount of deviation of the wafer W as the feature amount in addition to torque data of the motor of the transfer arm A3, the abnormality scale relating to the above-described transfer operation may be calculated more appropriately.

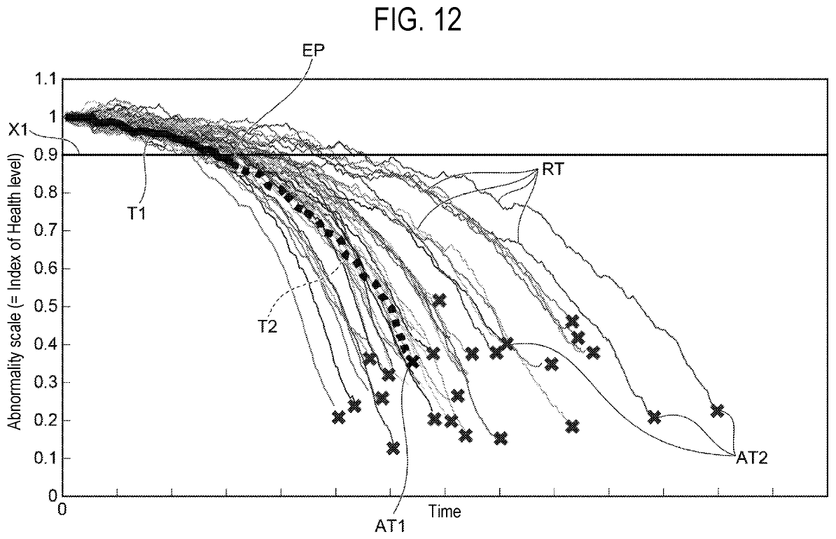

Although the present embodiment has been described above, the present embodiment is not limited to such an aspect. For example, in the specification operation of the above embodiment, at least one piece of reference data similar to the target data has been described as being specified by comparing the abnormality scale of the target data with the abnormality scale of the plurality of pieces of reference data. More specifically, in the specification operation, the at least one piece of reference data similar to the target data may be specified by comparing the trajectory RT (the movement trajectory, see FIG. 12) of the abnormality scale of the target data with the trajectory RT (the movement trajectory, see FIG. 12) of the abnormality scale of the plurality of pieces of reference data. The comparison between the movement trajectories may be performed, for example, based on a correlation coefficient or a mean absolute error. The trajectory RT of the abnormality scale of the target data is a movement trajectory of the abnormality scale in the first duration from the starting point in the target data to the predetermined time. The trajectory RT of the abnormality scale of the reference data is a movement trajectory of the abnormality scale of the comparison target duration from the starting point in the reference data to the time when the length equivalent to the first duration has elapsed. In this way, by comparing the movement trajectories of the abnormality scales with each other, the reference data having a transition of the abnormality scale similar to that of the target data may be appropriately specified. Thus, the abnormality occurrence prediction time of the target data may be predicted with high accuracy from the abnormality occurrence time of the reference data.

In the specification operation, the term “predetermined time” for determining the duration for acquiring the movement trajectory of the abnormality scale may be a time at which a value of the abnormality scale reaches a predetermined threshold. In the example illustrated in FIG. 12, a value 0.9 of the abnormality scale is set as a threshold X1. In this case, the movement trajectory of the first duration from the starting point in the target data to a time when the value of the abnormality scale reaches the threshold X1 (0.9) is extracted and used in the specification operation. The threshold X1 may be set to, for example, a time when a failure begins to occur statistically significantly based on information about a failure history of the device. Specifically, the threshold X1 may be set to a time when a slope of the movement trajectory becomes equal to or greater than a predetermined slope. In this way, since the movement trajectory up to the time when the value of the abnormality scale reaches the predetermined threshold is extracted and used in the specification operation, the movement trajectory of an appropriate duration may be extracted from the viewpoint of the value of the abnormality scale, and the abnormality occurrence prediction time in the target data may be predicted with high accuracy.

In addition, in the specification operation, in a case in which the reference data similar to the target data cannot be specified, a failure threshold of the value of the abnormality scale may be determined. In this case, in the estimation operation, the abnormality occurrence prediction time may be estimated based on a time until the value of the target data reaches the failure threshold. The case in which the reference data similar to the target data cannot be specified may mean, for example, a case in which there is little failure history information and thus little reference data.

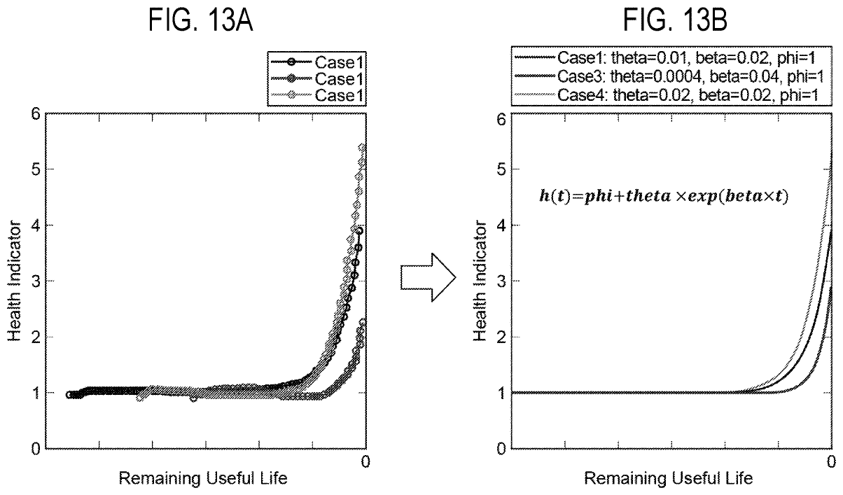

As a premise for performing the above processing, for example, an exponential degradation model is used. The exponential degradation model is a model that expresses a transition of a health indicator until a failure occurs. FIGS. 13A and 13B are diagrams for explaining the exponential degradation model. In FIGS. 13A and 13B, the horizontal axis indicates the remaining useful life and the vertical axis indicates the health indicator (abnormality scale). The health indicator is set to “1” at the start of the transfer operation and is set to a higher value as the health level decreases (the time-dependent deterioration progresses). In the example illustrated in FIG. 13A, the transition of the health indicator calculated from a feature amount of time-series torque data is illustrated in three cases: Case 1, Case 3, and Case 4. Now, as illustrated in FIG. 13B, the transition of the health indicator in each case may be expressed as a function of time using a combination of coefficients by fitting the health indicator with the exponential degradation model. The exponential degradation model is expressed by, for example, Equation (1) below. In the exponential degradation model, “theta” and “beta” are coefficients (parameters).

$$h ( t ) = phi + theta * exp ( beta * t ) \qquad ( 1 )$$

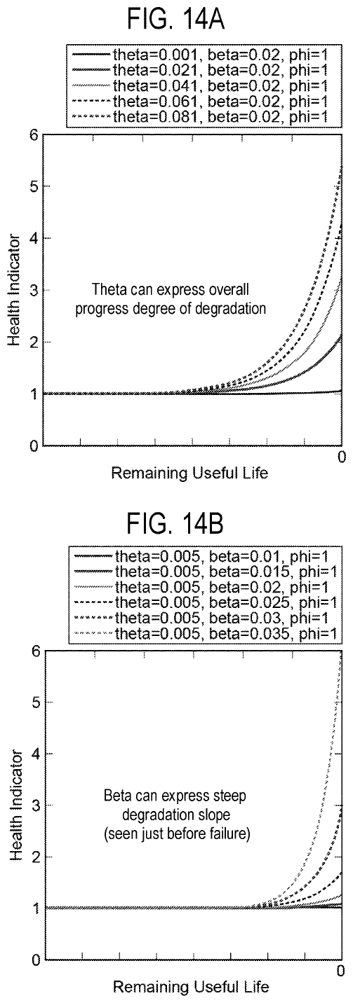

FIGS. 14A and 14B are diagrams for explaining effects of “theta” and “beta” in the exponential degradation model. In FIG. 14A, the behavior of the health indicator in a plurality of cases is illustrated while values of phi and beta are fixed and only a value of theta is variable. As illustrated in FIG. 14A, theta may express an overall degradation progress degree. In FIG. 14B, the behavior of the health indicator in the plurality of cases is illustrated while the values of phi and theta are fixed and only the value of beta is variable. As illustrated in FIG. 14B, beta may express a steep degradation slope seen just before failure.

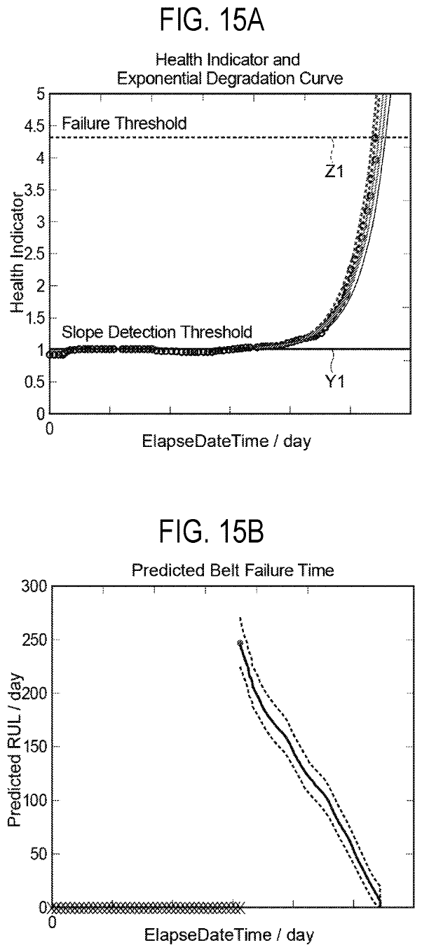

FIGS. 15A and 15B are diagrams for explaining estimation of the remaining useful life. In FIG. 15A, the horizontal axis indicates the elapsed time, and the vertical axis indicates the health indicator (abnormality scale). As illustrated in FIG. 15A, when the exponential degradation model is used, a slope detection threshold Y1 and a failure threshold Z1 are set. The slope detection threshold Y1 may be set to, for example, a maximum value of the health indicator observed when the belt is in a healthy state. The failure threshold Z1 may be determined based on history data such as past failure cases or on domain knowledge but may be set temporarily when data is insufficient. As illustrated in FIG. 15A, when the value of the target data exceeds the slope detection threshold Y1, a time until the value of the target data reaches the failure threshold Z1 is derived, and the remaining useful life is estimated. In FIG. 15B, the horizontal axis indicates the elapsed time, and the vertical axis indicates an estimated remaining useful life. As illustrated in FIG. 15B, the estimation of the remaining useful life begins from the time when the value of the target data exceeds the slope detection threshold Y1. A dashed line in FIG. 15B indicates an assumed range of errors.

The values of theta and beta, which are coefficients of the exponential degradation model, are accumulatively estimated by, for example, Bayesian updating. When the values of theta and beta, which are coefficients of the exponential degradation model, change by a certain value or more, the failure threshold Z1 is automatically offset up and down in conjunction with the change. That is, when the value of the coefficient increases by the certain value or more, the failure threshold is decreased (for example, changes from 0.40 to 0.35), and when the value of the coefficient decreases by the certain value or more, the failure threshold is increased (for example, changes from 0.40 to 0.45). In this way, the remaining useful life is estimated and output while offsetting the value of the failure threshold.

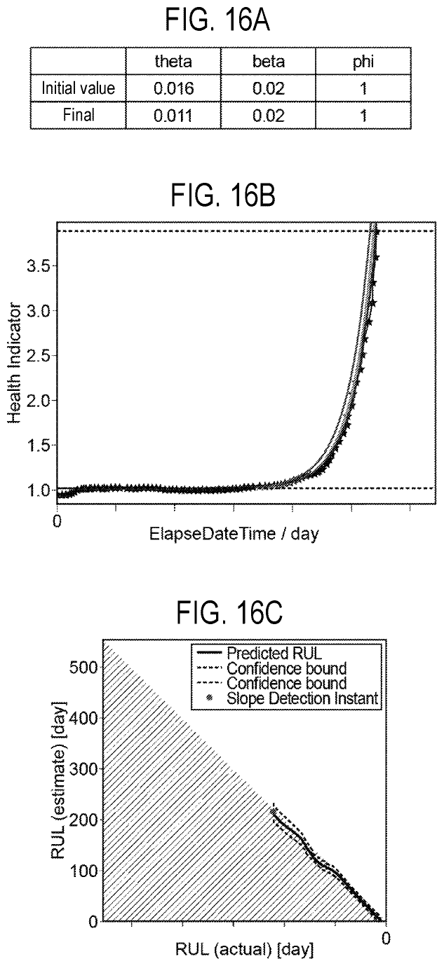

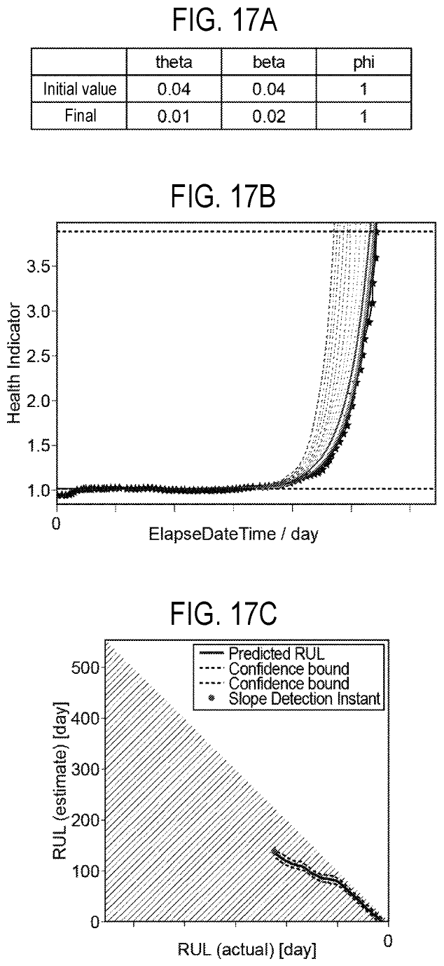

The value of the coefficient (parameter) of the exponential degradation model may improve an estimation precision degree of the remaining useful life from the start of the estimation by making an initial value of the coefficient closer to an optimal value. FIGS. 16A to 16C are diagrams for explaining estimation results of the remaining useful life when the initial value of the parameter is close to the optimal value. FIGS. 17A to 17C are diagrams for explaining estimation results of the remaining useful life when the initial value of the parameter deviates from the optimal value. In FIG. 16A and FIG. 17A, the initial value and the optimal value (final value) of each parameter are illustrated. In FIG. 16B and FIG. 17B, the horizontal axis indicates the elapsed time, and the vertical axis indicates the health indicator. In FIG. 16C and FIG. 17C, the horizontal axis indicates the actual remaining useful life, and the vertical axis indicates the estimated remaining useful life. As illustrated in FIG. 16C, when the initial value of the parameter is close to the optimal value, the estimation precision degree of the remaining useful life is high (close to the actual remaining useful life) from the start of the estimation. On the other hand, as illustrated FIG. 17C, when the initial value of the parameter deviates from the optimal value, the estimation precision degree of the remaining useful life is low (deviates from the actual remaining useful life) from the start of the estimation. In other words, unless sampling (number of data points) is increased to a certain extent, the model does not converge on an optimal exponential degradation model.

The initial value of the coefficient (parameter) of the exponential degradation model may be determined, for example, from previously-obtained failure history information. In this case, the coefficient of the exponential degradation model is associated with the previously-obtained failure history information. When diagnosing a new transfer arm, a coefficient of an associated exponential degradation model may be set to the initial value by referring to failure history information that has been stored as a database, and comparing that information with information such as a model, a type, or usage conditions of the transfer arm (the number of operations per day and a transfer speed) to extract the most recent information.

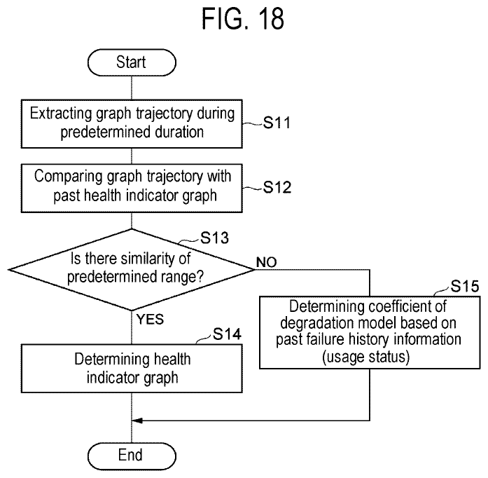

Lastly, an example of a procedure of an abnormality management method according to a modification example will be described with reference to FIG. 18. FIG. 18 is a flowchart illustrating the procedure of the abnormality management method according to the modification example. As illustrated in FIG. 18, first, a movement trajectory (graph trajectory) of an abnormality scale in target data during a predetermined duration is extracted based on a feature amount (Step S11). Subsequently, the movement trajectory of the abnormality scale in the target data is compared with a movement trajectory of an abnormality scale in a plurality of pieces of reference data (previous health indicator graph) (Step S12).

Thereafter, it is determined whether or not there is a movement trajectory of the reference data having similarity of a predetermined range with respect to the movement trajectory of the target data (Step S13). When it is determined in Step S13 that there is a movement trajectory of the reference data having such a similarity, the movement trajectory (health indicator graph) of the reference data is specified (Step S14), and an abnormality occurrence prediction time is estimated based on the movement trajectory of the reference data. On the other hand, when it is determined in Step S13 that there is no movement trajectory of the reference data having such a similarity, an initial value of a coefficient of an exponential degradation model is determined based on previous failure history information, and the abnormality occurrence prediction time is estimated (Step S15).

### EXPLANATION OF REFERENCE NUMERALS

2: Coating/developing apparatus (management apparatus), 100: Controller (control part), A3: Transfer arm (substrate transfer device), W: Wafer (substrate)

1. An abnormality management method used in a substrate transfer device configured to transfer a substrate, the abnormality management method comprising:
an acquisition operation of acquiring target data, which is transition data of an abnormality scale calculated based on a feature amount relating to a transfer operation of the substrate transfer device;
a specification operation of comparing the target data acquired in the acquisition operation with a plurality of pieces of reference data, which is pre-stored transition data acquired in a previous operation and defined as an abnormality occurrence, and specifying at least one piece of the reference data similar to the target data among the plurality of pieces of reference data based on a result of the comparison;
an estimation operation of estimating an abnormality occurrence prediction time in the substrate transfer device from which the target data has been acquired, based on an abnormality occurrence time in the at least one piece of reference data specified in the specification operation; and
an output operation of outputting information which indicates the abnormality occurrence prediction time estimated in the estimation operation.

2. The abnormality management method of claim 1, wherein, in the specification operation, the abnormality scale in a first duration from a starting point in the target data to a predetermined time is compared with an abnormality scale in a comparison target duration from a starting point in the plurality of pieces of reference data to a time when a length equivalent to the first duration has elapsed, to specify the at least one piece of reference data similar to the target data.

3. The abnormality management method of claim 1, wherein supplementary information including at least one of a type of the substrate transfer device, a type of a substrate processing apparatus equipped with the substrate transfer device, or a usage condition of the substrate transfer device is associated with the target data and the plurality of pieces of reference data, and
wherein, in the specification operation, the supplementary information associated with the target data is further compared with the supplementary information associated with each of the plurality of pieces of reference data, to specify the at least one piece of reference data in consideration of a similarity of the supplementary information.

4. The abnormality management method of claim 1, wherein, in the output operation, a user-visible image in which a trajectory of the target data and the abnormality occurrence prediction time are associated with each other on a graph is output.

5. The abnormality management method of claim 4, wherein, in the output operation, the user-visible image including a prediction trajectory which connects an end point of the trajectory of the target data and the abnormality occurrence prediction time on the graph is output.

6. The abnormality management method of claim 1, wherein the feature amount includes information about an amount of deviation of the substrate transferred by the substrate transfer device from a target transfer position.

7. The abnormality management method of claim 2, wherein, in the specification operation, a movement trajectory of the abnormality scale in the first duration from the starting point in the target data to the predetermined time is compared with a movement trajectory of the abnormality scale in the comparison target duration from the starting point in the plurality of pieces of reference data to the time when a length equivalent to the first duration has elapsed, to specify the at least one piece of reference data similar to the target data.

8. The abnormality management method of claim 2, wherein the predetermined time is a time when a value of the abnormality scale reaches a predetermined threshold.

9. The abnormality management method of claim 2, wherein, in the specification operation, when the at least one piece of reference data similar to the target data is not specified, a failure threshold of a value of the abnormality scale is determined, and
wherein, in the estimation operation, the abnormality occurrence prediction time is estimated based on a time until a value of the target data reaches the failure threshold.

10. A management apparatus for a substrate transfer device configured to transfer a substrate, the management apparatus comprising:
a controller configured to execute:
an acquisition operation of acquiring target data, which is transition data of an abnormality scale calculated based on a feature amount relating to a transfer operation of the substrate transfer device;
a specification operation of comparing the target data acquired in the acquisition operation with a plurality of pieces of reference data, which is pre-stored transition data acquired in a previous operation and determined to be abnormal, and specifying at least one piece of the reference data similar to the target data among the plurality of pieces of reference data based on a result of the comparison;
an estimation operation of estimating an abnormality occurrence prediction time in the substrate transfer device from which the target data has been acquired, based on an abnormality occurrence time in the at least one piece of reference data specified in the specification operation; and
an output operation of outputting information which indicates the abnormality occurrence prediction time estimated in the estimation operation.

11. The management apparatus of claim 10, wherein the controller is configured to compare the abnormality scale in a first duration from a starting point in the target data to a predetermined time with an abnormality scale in a comparison target duration from a starting point in the plurality of pieces of reference data to a time when a length equivalent to the first duration has elapsed, to specify the at least one piece of reference data similar to the target data.

12. The management apparatus of claim 10, wherein supplementary information including at least one of a type of the substrate transfer device, a type of a substrate processing apparatus equipped with the substrate transfer device, or a usage condition of the substrate transfer device is associated with the target data and the plurality of pieces of reference data, and
wherein the controller is configured to further compare the supplementary information associated with the target data with the supplementary information associated with each of the plurality of pieces of reference data, to specify the at least one piece of reference data in consideration of a similarity of the supplementary information.

13. The management apparatus of claim 10, wherein the controller is configured to output a user-visible image in which a trajectory of the target data and the abnormality occurrence prediction time are associated with each other on a graph.

14. The management apparatus of claim 13, wherein the controller is configured to output the user-visible image including a prediction trajectory which connects an end point of the trajectory of the target data and the abnormality occurrence prediction time on the graph.

15. The management apparatus of claim 10, wherein the feature amount includes information about an amount of deviation of the substrate transferred by the substrate transfer device from a target transfer position.

16. The management apparatus of claim 11, wherein the controller is configured to compare a movement trajectory of the abnormality scale in the first duration from the starting point in the target data to the predetermined time with a movement trajectory of the abnormality scale in the comparison target duration from the starting point in the plurality of pieces of reference data to the time when a length equivalent to the first duration has elapsed, to specify the at least one piece of reference data similar to the target data.

17. The management apparatus of claim 11, wherein the predetermined time is a time when a value of the abnormality scale reaches a predetermined threshold.

18. The management apparatus of claim 11, wherein the controller is configured to:
determine a failure threshold of a value of the abnormality scale when the at least one piece of reference data similar to the target data is not specified, and
estimate the abnormality occurrence prediction time based on a time until a value of the target data reaches the failure threshold.

19. A non-transitory computer-readable storage medium storing a program for causing an apparatus to execute the abnormality management method of claim 1.
